(19) United States
(12) Patent Application Publication
(10) Pub. No.: US 2016/0343787 A1
(43) Pub. Date: Nov. 24, 2016

(54) FLAT PANEL DISPLAY

(71) Applicant: SHENZHEN CHINA STAR OPTOELECTRONICS TECHNOLOGY CO., LTD., Shenzhen, Guangdong (CN)

(72) Inventor: Xiaoling WU, Shenzhen, Guangdong (CN)

(73) Assignee: Shenzhen China Star Optoelectronics Technology Co., Ltd., Shenzhen, Guangdong (CN)

(21) Appl. No.: 14/424,100

(22) PCT Filed: Feb. 8, 2015
(86) PCT No.: PCT/CN2015/072463

§ 371 Date: Feb. 26, 2015

(30) Foreign Application Priority Data
Nov. 28, 2014 (CN) 201410710448.2

(51) Int. Cl. H01L 27/32; H01L 51/52; G02F 1/1368; G02F 1/1333; G02F 1/1335

(52) U.S. Cl. CPC H01L 27/3262; G02F 1/133345; G02F 1/133524; G02F 1/133528; G02F 1/1368; G02F 1/133512; H01L 27/3276; H01L 51/5218; H01L 51/5234; G02F 2001/133357; G02F 2202/28

(57) ABSTRACT

The present invention provides a flat panel display. The flat panel display includes a non-transparent display zone (1), a transparent display zone (3) arranged in an outer circumference of the non-transparent display zone (1), and a plurality of environment detection devices (5) arranged under the transparent display zone (3). The non-transparent display zone (1) and the transparent display zone (3) are collectively covered by a transparent substrate (9). A black light absorption component (7) is arranged under the transparent display zone (3) and the plurality of environment detection devices (5). The flat panel display of the present invention includes a transparent display zone and a non-transparent display zone for collective displaying so as to effectively expand the displaying area and includes environment detection devices that are arranged under the transparent display zone to be concealed within the interior of the display with a black light absorption component arranged under the environment detection devices thereby making the outside configuration of the display good looking and overall aesthetics of the display enhanced.

### BACKGROUND OF THE INVENTION

1. Field of the Invention

The present invention relates to the field of displaying technology, and in particular to a flat panel display.

2. The Related Arts

In the field of displaying technology, flat panel displays, such as liquid crystal displays (LCDs) and organic light-emitting diodes (OLEDs), have been gradually taken the place of cathode ray tube (CRT) displays for wide applications in liquid crystal televisions, mobile phones, personal digital assistants (PDAs), digital cameras, computer monitors, and notebook computer screens.

Most of the liquid crystal displays that are currently available in the market are backlighting liquid crystal displays, which comprise an enclosure, a liquid crystal panel arranged in the enclosure, and a backlight module mounted in the enclosure. The liquid crystal panel itself does not emit light and light must be provided from the backlight module. The light from the backlight module is then refracted out by the liquid crystal panel to generate an image in order to normally display images. The backlight modules can be classified as a side-edge backlight module or a direct backlight module according to the site where light gets incident. The direct backlight module comprises a light source, such as a cold cathode fluorescent lamp (CCFL) or a light-emitting diode (LED), which is arranged at the backside of the liquid crystal panel to form a planar light source that is directly supplied to the liquid crystal display panel. The side-edge backlight module comprises an LED light bar, serving as a backlight source, which is arranged at an edge of a backplane to be located rearward of one side of the liquid crystal panel. The LED light bar emits light that enters a light guide plate (LGP) through a light incident face formed on one side of the light guide plate and is projected out of a light emergence face of the light guide plate, after being reflected and diffused, to pass through an optic film assembly so as to form a planar light source for the liquid crystal panel.

Compared to the LCD liquid crystal displays, the OLED organic light-emitting diode displays own various advantages, such as being self-luminous, low driving voltage, high light emission efficiency, short response time, high clarity and contrast, virtually 180° view angle, wide temperature range of applications, being capable of flexible displaying, and full color displaying in large area, and are considered a display device with the best potential of development.

The OLEDs can be classified, according to the type of driving, as passive OLEDs (such as passive matrix OLEDs (PMOLEDs)) and active OLEDs (such as active matrix OLEDs (AMOLEDs)). The AMOLEDs are generally a self-luminous device composed of a low-temperature poly-silicon (LTPS) driving backplane and an electroluminescent layer.

As shown in FIGS. 1 and 2, take a mobile phone display as an example, whether being an LCD or an OLED, a conventional flat panel display comprises a non-transparent display zone 100 and a non-display zone 300 arranged in an outer circumference of the non-transparent display zone 100. The non-display zone 300 is completely non-light-transmitting. An environment detection component 500 of a mobile phone, such as a camera and a touch key, which must detect the surrounding environment, is generally arranged in the non-display zone 300. In other words, the effective display area of a conventional display is limited to the non-transparent display zone 100 only and the display size is subjected to severe limitation in the uses thereof.

With the progress of the displaying technology, a transparent display becomes a novel fashion of technology. However, there are certain problems of the transparent display. Taking a mobile phone as an example, since it is still no possible to make certain components, such as batteries, microphones, and micro SD card receptacles, transparent, the display size and the outside aesthetics of the display are severely affected.

### SUMMARY OF THE INVENTION

An object of the present invention is to provide a flat panel display, which comprises a transparent display zone and a non-transparent display zone for collective displaying so as to effectively expand the displaying area and comprises an environment detection device that is arranged under the transparent display zone to be concealed in interior of the display with a black light absorption component arranged under the environment detection device thereby making the outside configuration of the display good looking and overall aesthetics of the display enhanced.

To achieve the above object, the present invention provides a flat panel display, which comprises a non-transparent display zone, a transparent display zone arranged in an outer circumference of the non-transparent display zone, and a plurality of environment detection devices arranged under the transparent display zone. The non-transparent display zone and the transparent display zone are collectively covered by a transparent substrate.

A black light absorption component is arranged under the plurality of environment detection devices.

The black light absorption component comprises a black adhesive tape.

The flat panel display comprises an organic light-emitting diode (OLED), which comprises a substrate that is made of transparent glass or plastics, a thin-film transistor (TFT) array that is made of a transparent oxide material to form a circuit pattern layer, a planarization layer and an insulation layer that are made of transparent organic and inorganic materials, an anode that is made of transparent indium tin oxide (ITO), and a cathode that is made of an ITO/Ag/ITO film so as to achieve transparent displaying.

The flat panel display comprises a liquid crystal display (LCD), which comprises transparent thin-film transistors (TFTs), polarizers, and light guide plate in order to achieve transparent displaying.

The transparent display zone achieves transparent displaying through spacing sub-pixels or reducing wiring width and film thickness to increase light transmittal.

The non-transparent display zone and the transparent display zone comprise identical pixel arrays so as to achieve continuous displaying with the non-transparent display zone and the transparent display zone.

The non-transparent display zone and the transparent display zone comprise different pixel arrays and use the same signal supplying devices to achieve continuous displaying with the non-transparent display zone and the transparent display zone.

In displaying an image, the non-transparent display zone and the transparent display zone perform collective displaying; and during not displaying an image, the plurality of environment detection devices function normally; and the plurality of environment detection devices include a camera, a sensor, and a touch key. The efficacy of the present invention is that the present invention provides a flat panel display, which comprises a transparent display zone and a non-transparent display zone for collective displaying so as to effectively expand the displaying area and comprises an environment detection device that is arranged under the transparent display zone to be concealed in interior of the display with a black light absorption component arranged under the environment detection device thereby making the outside configuration of the display good looking and overall aesthetics of the display enhanced.

For better understanding of the features and technical contents of the present invention, reference will be made to the following detailed description of the present invention and the attached drawings. However, the drawings are provided for the purposes of reference and illustration and are not intended to impose limitations to the present invention.

### BRIEF DESCRIPTION OF THE DRAWINGS

The technical solution, as well as other beneficial advantages, of the present invention will be apparent from the following detailed description of embodiments of the present invention, with reference to the attached drawing.

In the drawing:

FIG. 1 is a top plan view showing a conventional flat panel display;

FIG. 2 is a cross-sectional view taken along line A-A of FIG. 1;

FIG. 3 is a top plan view showing a flat panel display according to the present invention; and

FIG. 4 is a cross-sectional view taken along line B-B of FIG. 3.

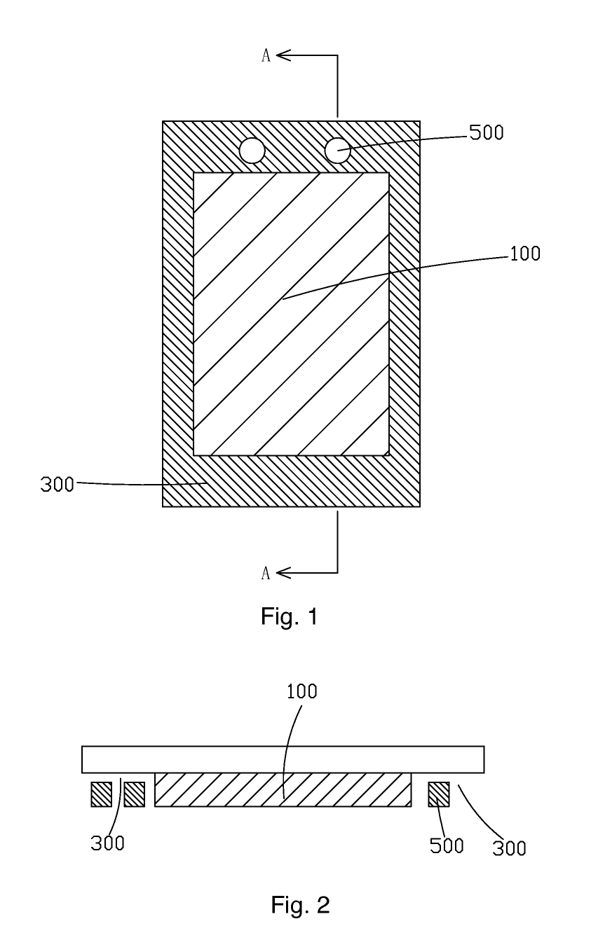

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

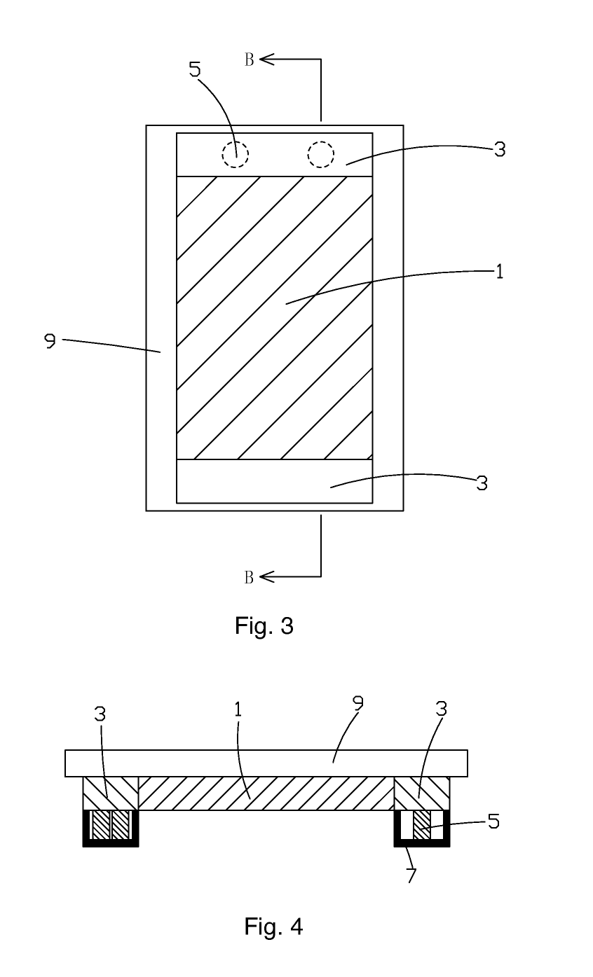

Referring collectively to FIGS. 3 and 4, the present invention provides a flat panel display, which comprises a non-transparent display zone 1, a transparent display zone 3 arranged in an outer circumference of the non-transparent display zone 1, and a plurality of environment detection devices 5 arranged under the transparent display zone 3. The non-transparent display zone 1 and the transparent display zone 3 are collectively covered by a transparent substrate 9. The flat panel display can be an OLED (Organic Light-Emitting Diode) or an LCD (Liquid Crystal Display).

Specifically, the plurality of environment detection devices 5 include devices that must detect the surrounding environment, such as a camera, a sensor, and a touch key.

Arranged under the plurality of environment detection devices 5 is a black light absorption component 7 and the black light absorption component 7 provides an effect of light absorption and light shielding. Preferably, the black light absorption component 7 comprises a black adhesive tape.

Further, the transparent display zone 3 can achieve transparent displaying by using a transparent material. For an example of an OLED, a substrate may be made of transparent glass or plastics; a thin-film transistor (TFT) array may be made of a transparent oxide material, such as indium tin oxide (ITO), to form a circuit pattern layer; a planarization layer and an insulation may be made of transparent organic materials or inorganic materials, such as silicon oxide; an anode may be made of transparent ITO and a cathode may be made of a ITO/Ag/ITO film having an increased thickness; and the OLED has an organic light emissive layer that is generally transparent. With the above-described materials that are all transparent, transparent displaying can be achieved. For an example of an LCD, transparent TFT, polarizers, and light guide plate can be used to achieve transparent displaying.

By using the transparent materials to achieve transparent displaying, the non-transparent display zone 1 and the transparent display zone 3 can be arranged to have identical pixel arrays so as to achieve continuous displaying with the non-transparent display zone 1 and the transparent display zone 3.

For both OLED and LCD, the transparent display zone 3 may achieve transparent displaying further through a design of a pixel arrangement, such as an arrangement of spaced sub-pixels, where a specific distance is provided between the sub-pixels of a column or a row of the sub-pixels so as to reduce the number of sub-pixels in a unit area and thus reducing the sub-pixel density, or alternatively, through reducing wiring width and film thickness to increase light transmittal. Under this condition, the non-transparent display zone 1 and the transparent display zone 3 may be of different pixel arrays but use the same signal supplying device, such as using chip-on-FPC (C)OF) having different pin numbers to achieve continuous displaying of the non-transparent display zone 1 and the transparent display zone 3. In displaying an image, the non-transparent display zone 1 and the transparent display zone 3 are used to collectively perform the displaying so as to achieve the purpose of expanding the area of the displaying area; and in case of not displaying an image, since the transparent display zone 3 and the transparent substrate 9 that are arranged above the plurality of environment detection devices 5 are both transparent, the plurality of environment detection devices 5 may function normally; and since the black light absorption component 7 that is arranged under the plurality of environment detection devices 5 may absorb light transmitting through the transparent display zone 3, the plurality of environment detection devices 5 become invisible from the outside of the display thereby achieving concealing the environment detection devices 5 within the interior of the display and thus making the outside configuration of the display good looking and overall aesthetics of the display enhanced.

In summary, the present invention provides a flat panel display, which comprises a transparent display zone and a non-transparent display zone for collective displaying so as to effectively expand the displaying area and comprises an environment detection device that is arranged under the transparent display zone to be concealed in interior of the display with a black light absorption component arranged under the environment detection device thereby making the outside configuration of the display good looking and overall aesthetics of the display enhanced.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A flat panel display, comprising a non-transparent display zone, a transparent display zone arranged in an outer circumference of the non-transparent display zone, and a plurality of environment detection devices arranged under the transparent display zone, the non-transparent display zone and the transparent display zone being collectively covered by a transparent substrate.

2. The flat panel display as claimed in claim 1, wherein a black light absorption component is arranged under the plurality of environment detection devices.

3. The flat panel display as claimed in claim 2, wherein the black light absorption component comprises a black adhesive tape.

4. The flat panel display as claimed in claim 1, wherein the transparent display zone achieves transparent displaying by using a transparent material.

5. The flat panel display as claimed in claim 4, wherein the flat panel display comprises an organic light-emitting diode (OLED), which comprises a substrate that is made of transparent glass or plastics, a thin-film transistor (TFT) array that is made of a transparent oxide material to form a circuit pattern layer, a planarization layer and an insulation layer that are made of transparent organic and inorganic materials, an anode that is made of transparent indium tin oxide (ITO), and a cathode that is made of an ITO/Ag/ITO film so as to achieve transparent displaying.

6. The flat panel display as claimed in claim 4, wherein the flat panel display comprises a liquid crystal display (LCD), which comprises transparent thin-film transistors (TFTs), polarizers, and light guide plate in order to achieve transparent displaying.

7. The flat panel display as claimed in claim 1, wherein the transparent display zone achieves transparent displaying through spacing sub-pixels or reducing wiring width and film thickness to increase light transmittal.

8. The flat panel display as claimed in claim 4, wherein the non-transparent display zone and the transparent display zone comprise identical pixel arrays so as to achieve continuous displaying with the non-transparent display zone and the transparent display zone.

9. The flat panel display as claimed in claim 7, wherein the non-transparent display zone and the transparent display zone comprise different pixel arrays and use the same signal supplying devices to achieve continuous displaying with the non-transparent display zone and the transparent display zone.

10. The flat panel display as claimed in claim 1, wherein in displaying an image, the non-transparent display zone and the transparent display zone perform collective displaying; and during not displaying an image, the plurality of environment detection devices function normally; and the plurality of environment detection devices include a camera, a sensor, and a touch key.

11. A flat panel display, comprising a non-transparent display zone, a transparent display zone arranged in an outer circumference of the non-transparent display zone, and a plurality of environment detection devices arranged under the transparent display zone, the non-transparent display zone and the transparent display zone being collectively covered by a transparent substrate;
wherein a black light absorption component is arranged under the plurality of environment detection devices;
wherein the transparent display zone achieves transparent displaying by using a transparent material;
wherein the transparent display zone achieves transparent displaying through spacing sub-pixels or reducing wiring width and film thickness to increase light transmittal; and
wherein in displaying an image, the non-transparent display zone and the transparent display zone perform collective displaying; and during not displaying an image, the plurality of environment detection devices function normally; and the plurality of environment detection devices include a camera, a sensor, and a touch key.

12. The flat panel display as claimed in claim 11, wherein the black light absorption component comprises a black adhesive tape.

13. The flat panel display as claimed in claim 11, wherein the flat panel display comprises an organic light-emitting diode (OLED), which comprises a substrate that is made of transparent glass or plastics, a thin-film transistor (TFT) array that is made of a transparent oxide material to form a circuit pattern layer, a planarization layer and an insulation layer that are made of transparent organic and inorganic materials, an anode that is made of transparent indium tin oxide (ITO), and a cathode that is made of an ITO/Ag/ITO film so as to achieve transparent displaying.

14. The flat panel display as claimed in claim 11, wherein the flat panel display comprises a liquid crystal display (LCD), which comprises transparent thin-film transistors (TFTs), polarizers, and light guide plate in order to achieve transparent displaying.

15. The flat panel display as claimed in claim 11, wherein the non-transparent display zone and the transparent display zone comprise identical pixel arrays so as to achieve continuous displaying with the non-transparent display zone and the transparent display zone.

16. The flat panel display as claimed in claim 11, wherein the non-transparent display zone and the transparent display zone comprise different pixel arrays and use the same signal supplying devices to achieve continuous displaying with the non-transparent display zone and the transparent display zone.
